(19) United States
(12) Patent Application Publication
(10) Pub. No.: US 2019/0032233 A1
(43) Pub. Date: Jan. 31, 2019

(54) LIGA FABRICATION PROCESS

(71) Applicant: Master Dynamic Limited, Shatin, New Territories (CN)

(72) Inventors: Yingnan WANG, Shatin, HK (CN); Ching Tom KONG, Wang Toi Shan, HK (CN)

(21) Appl. No.: 16/080,656

(22) PCT Filed: Mar. 1, 2017
(86) PCT No.: PCT/CN2017/075351

§ 371 Date: Aug. 28, 2018

(30) Foreign Application Priority Data
Feb. 29, 2016 (HK) 16102324.5

(51) Int. Cl. C25D 1/00; G03F 7/00

(52) U.S. Cl. CPC C25D 1/003; G03F 7/0037; G03F 7/0002

(57) ABSTRACT

A process of forming a three-dimensional micro component includes the step of forming a three-dimensional (3D) geometry contour within a photoresist material using two-photon absorption polymerization. The three-dimensional geometry contour forms a cross-linked polymeric contour defining an outer surface portion of a micro component upon baking of the three-dimensional geometry portion formed in the photoresist. Another step involves applying a UV (ultraviolet) polymerization process so as to cross-link polymeric material of the photoresist adjacent the three-dimensional geometry contour.

### TECHNICAL FIELD

The present invention relates to a method of forming micro components, in particular the present invention relates to micro components formed by using LIGA, Lithographie, Galvanoformung, Abformung (Lithography, Electroplating, and Molding) micro molding process.

### BACKGROUND OF THE INVENTION

With the advent of miniaturization of mechanical and electrical devices and components, there exists a high requirement for the fabrication of micro components having high and consistent dimensional accuracy and tolerances.

Due to the 2D (two-dimensional) design versatility and high fabrication precision by utilisation of photolithography techniques, as is known X-ray LIGA and UV-LIGA technologies may be considered relatively commonly utilised for the fabrication and generation micro components.

Within the art, X-ray LIGA provides the advantageous characteristics including high aspect ratio (in the order of 100:1), straight sidewall component characteristics having a high mirror-like smoothness, and structure heights ranging from tens of micrometers to several millimeters and having ultrahigh resolution.

X-ray LIGA typically utilizes an X-ray sensitive polymer photoresist which is typically PMMA (polymethyl methacrylate), for the polymer molding process. The type of X-ray required for such a process typically provides parallel beams of high-energy X-ray from a synchrotron radiation source. However, such an X-ray source is not widely available and is often considered prohibitively expensive and costly for manufacturing.

In comparison with an X-ray LIGA process, UV-LIGA (ultraviolet LIGA) utilizes a relatively inexpensive UV light source which is used to provide exposure to a polymer photoresist, typically SU-8 (an epoxy-based negative photoresist).

UV-LIGA is typically considered considerably less expensive and more readily accessible than the X-ray LIGA counterpart. However, when utilisation of UV-LIGA is effected, the achievement of a high aspect ratio and a component height is typically limited to several hundred micrometers. Furthermore, the sidewall roughness of a component formed by such a technique has been found to increase undesirably in particular applications very significantly with the component height.

Micro components formed by utilisation of any LIGA process are typically limited to 2.5D (two and a half dimensions). Different methods within the prior art are utilized for achieving and providing 2.5D micro components or multi-level components.

By way of example, Mimotec S.A. utilizes a method of building a metal component layer by layer, such as is disclosed in EP 2405300 (Mimotech S.A.). In such a process, when a first metal layer is deposited by electroforming, the top surface is machined and treated so as to provide for the building of another layer on top. There exists the requirement for providing adhesion between different layers and in such a process a specialised structure is required for enhancing the bonding strength between layers, and a specialised chemical treatment process is required to be effected prior to building a new metal layer atop of the previously electroformed layer. Each different layer in such a process is required to be precisely aligned with the layer beneath it. With an increasing number of layers of material in structure or component formed according to such a method, there is typically an effect of accumulated alignment error, which results in a final electroformed component which may not possess the requisite dimensional accuracy for such a component. Furthermore, there exists complexity of manufacturing in the provision of the adhesion process between layers of such a process.

### OBJECT OF THE INVENTION

It is an object of the present invention to provide a process which overcomes or substantially ameliorates at least some of the deficiencies as associated with those of the prior art.

### SUMMARY OF THE INVENTION

In a first aspect, the present invention provides a process of forming a three-dimensional 3D micro components, said process including the steps of (i) forming a three-dimensional geometry contour within a photoresist material using two-photon absorption polymerization, wherein the three-dimensional geometry contour forms a cross-linked polymeric contour defining an outer surface portion of a micro component upon the three-dimensional geometry portion formed in the photoresist having been baked, and (ii) applying a UV (ultraviolet) polymerization process so as to cross-link polymeric material of the photoresist adjacent said three-dimensional geometry contour.

In a first embodiment of the present aspect, said three-dimensional geometry contour forms a closed shell defining a mold cavity which defines the shape and geometry for the formation of a micro component therein, and further including the step of developing the photoresist so as to provide a mold cavity within the closed shell, and wherein the step of polymerizing the photoresist by way of an UV (ultraviolet) polymerization process cross-links the photoresist material so as to form a mold for the formation of the micro component therein.

The present embodiment may further include the step forming the micro component within the mold cavity by way of an electroforming process, whereby the micro component is formed from a metal or metal alloy material.

A further step of the present embodiment may include removing photoresist surrounding the micro component so as to expose the micro component.

In another embodiment of the present aspect, following step (i) baking of the photoresist, the process further includes the step of removing photoresist external of the three-dimensional geometry contour prior to step (ii) of exposing the remaining photoresist by way of UV (ultraviolet) polymerization process such that the photoresist is polymerized so as the photoresist forms a polymeric micro component.

In a second aspect of the invention, there is provided a micro component formed according to the process of the first aspect.

The micro component may be a component for a mechanical time piece. Alternatively, the micro component may be a component for medical instruments.

In a third aspect, the present invention provides a process of forming a mold for formation of three-dimensional micro component, said process including the steps of (i) forming a three-dimensional (3D) geometry contour within a photoresist material using two-photon absorption polymerization, wherein the three-dimensional geometry contour forms a cross-linked polymeric contour defining an outer surface portion of a micro component upon the three-dimensional geometry portion formed in the photoresist having been baked; and (ii) applying a UV (ultraviolet) polymerization process so as to cross-link polymeric material of the photoresist adjacent said three-dimensional geometry contour; wherein said three-dimensional geometry contour defines a mold cavity for the formation of a three-dimensional micro component therein; and wherein adjacent said three-dimensional geometry contour provides a body of the mold.

In a fourth aspect, the present invention provides a mold for forming a three-dimensional micro component, wherein the mold is formed according to the process of the third aspect.

In a fifth aspect, the present invention provides a process of forming a three-dimensional micro component, said process including the steps of (i) forming a three-dimensional (3D) geometry contour within a photoresist material using two-photon absorption polymerization, wherein the three-dimensional geometry contour forms a cross-linked polymeric contour defining an outer surface portion of a micro component upon the three-dimensional geometry portion formed in the photoresist having been baked; (ii) removing photoresist external of the three-dimensional geometry; and (iii) applying a UV (ultraviolet) polymerization process so as to cross-link polymeric material of the photoresist adjacent said three-dimensional geometry contour; wherein said three-dimensional geometry contour forms an outer surface of a three-dimensional micro component; and wherein the cross-linked polymeric material of the photoresist adjacent said three-dimensional geometry contour forms the body of said three-dimensional micro component.

In a sixth aspect, the present invention provides a three-dimensional micro component formed according to the process of the fifth aspect.

As will be understood, the present invention provides a process that utilises two-photon absorption polymerization and UV polymerization, which can generate a three-dimensional polymer micro component, as well as a three-dimensional micro mold for the electroforming process.

In the two-photon absorption polymerization process, a photoresist containing monomers and a 2-photon active photoinitiator, such as SU-8, may be utilized for forming the micro components. The application of a focused laser to the photoresist results in polymerization only at the focal spot of the laser, where the intensity of the absorbed light is highest. The shape of a requisite object can therefore be traced out by the laser, and then the excess photoresist can be washed away to leave the traced solid.

Two-photon absorption polymerization is a direct laser writing technology, with which the three-dimensional polymer mold for micro component electroforming may be written without any alignment issue between all levels.

With current technology, the smallest feature size can reach as small as 150 nm, and the surface roughness can be as low as several tens of angstroms.

The present invention utilizes such techniques by using the three-dimensional geometry design freedom and absence of constraints, such that a component with any shape can be written with two-photon absorption polymerization.

The strength of two-photon absorption polymerization is to generate ultra-fine contour in 3D geometry, while UV polymerization on the contrary is an efficient polymerization process. The idea of this present invention is to combine the two-photon absorption and UV polymerization, taking the advantages of both parties.

### BRIEF DESCRIPTION OF THE DRAWINGS

Examples of the invention will now be described with reference to the accompanying drawings, in which:

FIG. 1(a) to FIG. 1(e) depict a schematic representation an example of an embodiment of a process in accordance with the present invention for the formation of a the balance screw for utilisation in a timepiece regulator for the adjustment of the oscillating frequency of the timepiece, by combining the processes of two-photon absorption and UV polymerization, followed by electroforming; and

FIG. 2(a) to FIG. 2(d) depict a schematic representation of an example an embodiment of a process according to the present invention, for the formation of a fastener formed from a polymeric material, by combining two-photon absorption and UV polymerization.

### DETAILED DESCRIPTION OF THE DRAWINGS

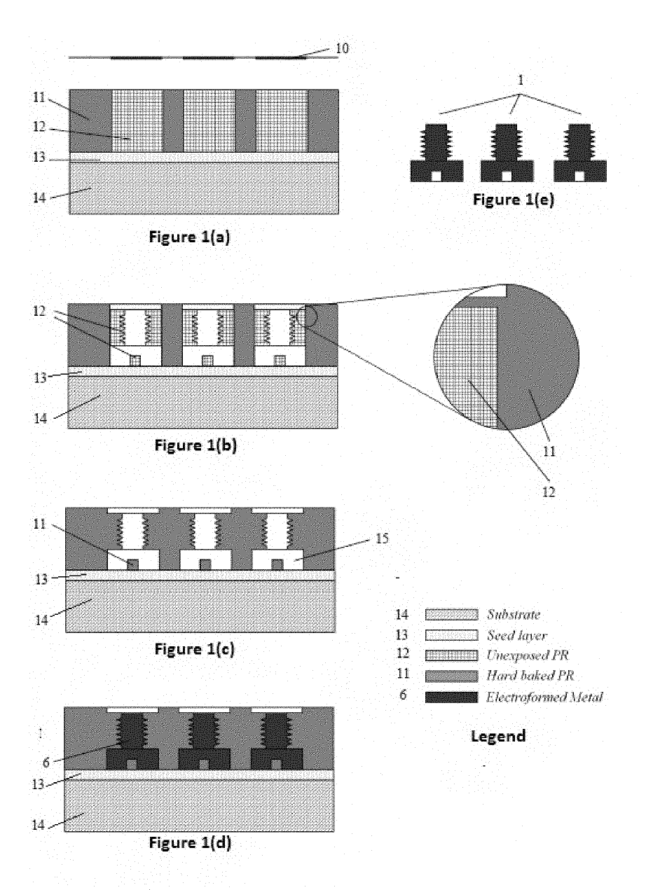

Referring to FIGS. 1(a), 1(b), 1(c) and 1(d), there is shown a schematic representation an example of a process in accordance with the present invention for the formation of a balance screw for utilisation in a timepiece regulator for the adjustment of the oscillating frequency of the timepiece, by combining two-photon absorption and UV polymerization, followed by electroforming. With reference to FIG. 1(e), there is shown a sectional view of a component formed from the process as described with reference to FIGS. 1(a), 1(b), 1(c) and 1(d), in this example a balance screw 1 as utilized in timepieces for explanatory purposes of the process according to the present invention.

As shown in FIG. 1(a) in accordance with the process of the present invention, a substrate 14 is initially coated with conductive seed layer 13, which is typically a relatively thick layer of metal, which is formed by a sputtering process, with a thickness typically of about 100 nm.

The seed layer 13 coated substrate 14 is covered by a photoresist 11,12, which in the present example is SU-8, which is an epoxy-based negative photoresist. The term “negative” refers to a photoresist whereby the parts exposed to UV become cross-linked, while the remainder of the film remains soluble and can be washed away during development.

A standard photolithography process as known by those skilled in the art may be deployed, whereby the unexposed photoresist 12 is covered by a photomask 10 during the photolithography process, and whereby 11 is the portion of the exposed photoresist.

As shown in FIG. 1(b), upon the exposed photoresist 11 having been hard baked during the process, the photoresist then provides a supporting structure for the following step of two-photon absorption laser writing.

A laser beam from a two-photon absorption laser writing device is used to expose a contour of a component, in this example the contour of the shape of a balance screw 1.

Upon the patterned substrate 14 having been baked, the photoresist having been exposed by two-photon laser beam along the balance screw 1 contour will be cross-linked, so as to form a closed shell.

After said cross-linking has been provided by the process, the photoresist is then developed in a developer, which results in a photoresist mold 15 having the geometric requirements for the balance screw 1.

Referring to FIG. 1(c), a UV (ultraviolet) polymerization process is then performed, after which the substrate 14 is baked again, so as to cross-link the exposed photoresist 11. The substrate 14 is then ready to be placed within an electroforming tank as described with reference to FIG. 1(d) as follows.

FIG. 1(d) depicts electroformed metal 16 filling the photoresist mold 15 as formed and as described above, so as to form an electroformed balance screw 1 for subsequent release from the substrate.

Upon release from the substrate and removal and stripping of the photoresist, the fabrication of the balance screw 1 as shown in FIG. 1(e) has been completed.

As will be understood and appreciated, the present invention has been described with reference to the formation of a mold in accordance with the present invention for manufacture of metal balance spring for explanatory purposes.

In other and alternate applications and implementations, there exists the case, whereby the mechanical strength of a component is not a predominant or necessarily a requisite design and component requirement, however high dimensional accuracy is a requisite parameter. In such cases, a polymeric material, for example, may be used as the material from which the final component is formed.

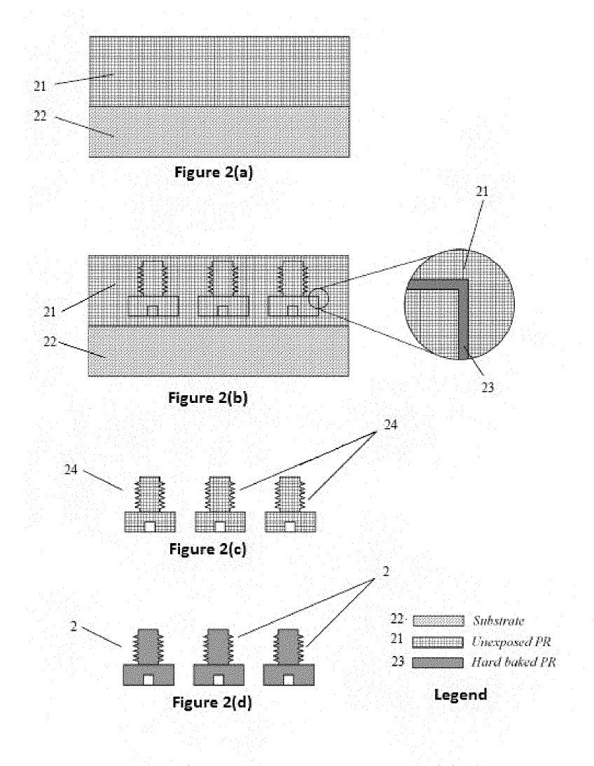

By way of example of another embodiment of the present invention, for the formation of a component formed from a polymeric material, a process for the formation of a balance screw 2 is used in reference to accompanying FIGS. 2(a) to 2(d).

As shown in the example of FIGS. 2(a) to 2(d), in FIG. 2(a) a substrate 22 is coated with a photoresist 21, which has been soft baked.

A two-photon laser beam is utilized to scan the requisite contour 23 of the balance screw 2, as depicted in FIG. 2(b). Then, upon the substrate 22 having been hard baked, the photoresist 21 in the contour 23 region is caused to become cross-linked, forming a closed shell from the photoresist polymeric material.

Referring to FIG. 2(c), a developer is then utilized to remove the photoresist 21 outside the contour 23, and a partially finished balance screw 24 is then formed from the photoresist 21. The formation of the partially finished balance screw 24 formed from the photoresist 21 has then been completed.

Following the formation of the balance screw 24 of photoresist 21 as described above in reference to FIG. 2(c), the partially finished balance screw 24 of photoresist is then exposed with UV light by way of a UV (ultraviolet) polymerization process and hard baked, resulting in the requisite balance screw 2 as depicted in FIG. 2(d).

The present invention provides a process for the formation of micro components having increased and high dimensional accuracy and tolerances in comparison with processes as described by the prior art, and such micro-components may be provided in a three-dimensional (3D) form, by providing a micro molding and formation process which is based on two-photon absorption polymerization, combined with UV polymerization.

Furthermore, the present invention provides a process for the formation of micro components of consistent and repeatable high dimensional accuracy, without the necessity of providing multiple layer constructs and as such the present invention obviates the necessity of alignment and the associated inaccuracy exposure, as well as obviates the necessity for adhesion between the layers which is a deficiency as associated with the prior art.

Still further, the present invention provides for the formation of micro components from different materials, such as metal or metal alloy materials, as well as micro components formed from polymeric materials. As such, micro components as provided and formed according to the present invention may be provided for applications whereby component mechanical strength is a design requirement, such as providing fasteners such as screws as utilized in the description for illustrative purposed, which may be exposed to stress and loading such as cyclic loading.

Furthermore, in other applications whereby mechanical strength is not a significant design parameter which requires metallic components, the present invention provides for the formation of polymeric components, which may also in particular applications be applicable when design parameters dictate low mass components or non-magnet components, for example.

As such, the present invention provides for the following, providing advantages over the prior art whilst addressing deficiencies associated with the prior art:
(i) High dimensional accuracy component, which is repeatable,
(ii) Obviates alignment and layering steps,
(iii) Allows for a full three-dimensional (3D) micro component to be formed, and thus is not restricted to applications configured for implementation of 2.5D (two and a half dimensions),
(iv) Provides for the formation of micro components which are not limited to only hundred micrometers such as in the prior art, and
(v) Allows for fabrication of components formed from metallic and polymeric components, thus providing versatility as to material applications and component requirements, such as strength requirements, aesthetic requirements, and environmental requirements.

The present invention has been described above for illustrative purposes in reference to the formation of screws, such as balance screws as utilized in mechanical time pieces. However, such examples are not to be considered restrictive and as will be readily appreciated by those skilled in the art, the formation of other micro components by utilisation of the present invention are considered equally applicable without departing from the scope of the invention.

Although the present invention has been described with reference to micro components for use in mechanical timepieces, other commercial applications are equally as applicable whereby micro components are required, such as other micro mechanical devices or assemblies, without departing from the scope of the invention. As will be understood, formation of micro components is applicable to other fields of usage such a biomedical applications, micro machines and devices and the like.

As will be understood and appreciated by those skilled in the art, numerous embodiments to the present aspect exist, and the above examples are not restrictive, as other examples are equally as applicable for implementation in alternate embodiments.

1. A process of forming a three-dimensional micro component, said process including the step of:
(i) forming a three-dimensional (3D) geometry contour within a photoresist material using two-photon absorption polymerization, wherein the three-dimensional geometry contour forms a cross-linked polymeric contour defining an outer surface portion of a micro component upon the three-dimensional geometry portion formed in the photoresist having been baked; and
(ii) applying a UV (ultraviolet) polymerization process so as to cross-link polymeric material of the photoresist adjacent said three-dimensional geometry contour.

2. A process according to claim 1, wherein said three-dimensional geometry contour forms a closed shell defining a mold cavity which defines the shape and geometry for the formation of a micro component therein, and further including the step of developing the photoresist so as to provide a mold cavity within the closed shell, and wherein the step of polymerizing the photoresist by way of an UV (ultraviolet) polymerization process cross-links the photoresist material so as to form a mold for the formation of the micro component therein.

3. A process according to claim 2, further including a step forming a micro component within the mold cavity by way of an electroforming process, whereby the micro component is formed from a metal or metal alloy material.

4. A process according to claim 3, further including the step of removing photoresist surrounding the micro component so as to expose the micro component.

5. A process according to claim 1, wherein following step (i) baking of the photoresist, the process further includes the step of removing photoresist external of the three-dimensional geometry contour prior to step (ii) of exposing the remaining photoresist by way of UV (ultraviolet) polymerization process such that the photoresist is polymerized so as the photoresist forms a polymeric micro component.

6. A micro component formed according to the process of claim 1.

7. A micro components according to claim 6, wherein the micro component is a component for a mechanical time piece.

8. A micro components according to claim 6, wherein the micro component is a component for medical instruments.

9. A process of forming a mold for formation of three-dimensional micro component, said process including the steps of
(i) forming a three-dimensional (3D) geometry contour within a photoresist material using two-photon absorption polymerization, wherein the three-dimensional geometry contour forms a cross-linked polymeric contour defining an outer surface portion of a micro component upon the three-dimensional geometry portion formed in the photoresist having been baked; and
(ii) applying a UV (ultraviolet) polymerization process so as to cross-link polymeric material of the photoresist adjacent said three-dimensional geometry contour;
wherein said three-dimensional geometry contour defines a mold cavity for the formation of a three-dimensional micro component therein; and
wherein adjacent said three-dimensional geometry contour provides a body of the mold.

10. A mold for forming a three-dimensional micro component, wherein the mold is formed according to the process of claim 9.

11. A process of forming a three-dimensional micro component, said process including the steps of:
(i) forming a three-dimensional (3D) geometry contour within a photoresist material using two-photon absorption polymerization, wherein the three-dimensional geometry contour forms a cross-linked polymeric contour defining an outer surface portion of a micro component upon the three-dimensional geometry portion formed in the photoresist having been baked;
(ii) removing photoresist external of the three-dimensional geometry; and
(iii) applying a UV (ultraviolet) polymerization process so as to cross-link polymeric material of the photoresist adjacent said three-dimensional geometry contour;
wherein said three-dimensional geometry contour forms an outer surface of a three-dimensional micro component; and
wherein the cross-linked polymeric material of the photoresist adjacent said three-dimensional geometry contour forms the body of said three-dimensional micro component.

12. A three-dimensional micro component formed according to the process of claim 11.
